(19) United States
(12) Patent Application Publication
(10) Pub. No.: US 2012/0017742 A1
(43) Pub. Date: Jan. 26, 2012

(54) Saw Band and Method for the Production of a Saw Band

(75) Inventor: Michael BALINT, Dischingen (DE)

(73) Assignee: Oerlikon Trading AG, Trubbach, Trubbach (CH)

(21) Appl. No.: 13/197,681

(22) Filed: Aug. 3, 2011

Related U.S. Application Data
(62) Division of application No. 11/895,302, filed on Aug. 24, 2007, now abandoned.
Application No. 11/895,302 is a continuation-in-part of application No. PCT/EP06/01669, filed on Feb. 23, 2007.

(30) Foreign Application Priority Data
Feb. 24, 2005 (DE) 10 2005 008 810.4
Apr. 12, 2005 (DE) 10 2005 016 953.8
Sep. 13, 2005 (DE) 10 2005 043 527.0

(51) Int. Cl. B23D 61/12; B23P 17/00; C23C 16/50; C23C 16/44; F01N 13/18

(52) U.S. Cl. 83/661; 427/248.1; 228/176; 427/569; 29/527.4

(57) ABSTRACT

A saw band of steel for a band-sawing machine has a band back and a row of teeth having a number of teeth, at least the row of teeth being provided with a hard material coating. According to the invention, this coating comprises one or more metals of subgroups IV, V or VI of the periodic system or aluminum or silicon and/or their nitrites, oxides, carbides, carbonitrides or borides of the aforementioned metals or mixtures thereof. A method according to the invention is a vacuum coating method, for example as PVD or paCVD.

### CROSS REFERENCE TO RELATED PATENT APPLICATIONS

This patent application is a Continuation-In-Part Application which claims priority to International Application No. PCT/EP2006/001669, filed Feb. 23, 2006, entitled Saw Band and Method for the Production of a Saw Band, naming Michael Balint as inventor, and which claims priority to German Patent No. 10 2005 043 527.0, filed Sep. 13, 2005; German Patent No. 10 2005 016 953.8, filed Apr. 12, 2005; and German Patent No. 10 2005 008 810.4, filed Feb. 24, 2005; and the disclosures of each application are incorporated herein by reference.

### FIELD OF THE INVENTION

The The invention relates to a saw band for a circulating band-sawing machine. Furthermore, the invention relates to a method for the production of a saw band.

### BACKGROUND OF THE INVENTION

A saw band of the prior art is known for example from DE 102 02 770 A1. It is used in band-sawing machines, as described for example in DE 25 38 718 A1 and used in particular for sawing large workpieces that cannot be worked with circular saws. In spite of very great efforts with respect to improved material compositions for these saw bands, they are however only designed or suitable for relatively low cutting speeds and small feed rates and have very short edge lives, i.e. they usually become blunt very quickly and must be exchanged correspondingly often.

It is also known to provide tools and components with coatings to increase wear resistance and corrosion protection. Frequently, PVD (physical vapor deposition) or paCVD (plasma assisted chemical vapor deposition) methods or combinations of these are used for this purpose.

The publication WO 2005/014877 A1 discloses the coating of a steel strip in a roll-to-roll process, a layer of various hard materials being applied to one side, or in successive process steps to both sides, of the strip produced with preference from cold work steel. Subsequently, a saw band can be produced from this strip.

A disadvantage in this case is that the coating is performed from the side. Consequently, the smallest layer thickness is applied to the functional faces that are exposed most to wear (tool flank & tool face) and the greatest layer thickness is applied to the side faces that are subjected to less loading, and consequently the costly coating material is poorly used. Moreover, the coating is often applied to cold work steels, which are only hardened subsequently, which may have disadvantageous effects on the layer/substrate bond. On the other hand, such cold work steels cannot be readily coated after hardening, since customary PVD processes far exceed the annealing temperature of such materials. Low-temperature PVD processes have in turn the disadvantage of producing layers with inferior adhesive bonding, which is a major disadvantage precisely in cases where there is great loading, as in the case of sawing, and abrasive wear. A further disadvantage is caused by the roll-to-roll process proposed in the prior art. This does not allow every saw geometry to be chosen, for example a set tooth geometry is not possible, since such bands cannot be wound, or only poorly. Since the layer thicknesses known in the prior art are much greater than 5 μm, they are expensive to produce and do not provide any significant improvement over uncoated saws, since there is the tendency for the layer to break off at the tip of the saw during running in, and consequently the advantages of the coating no longer have any effect there.

### SUMMARY OF THE INVENTION

It is therefore the object of the present invention to provide a saw band for a band-sawing machine and a method for the production of such a saw band that make it possible to obtain a much better performance, especially when working metallic materials. Furthermore, the cost-effectiveness is to be improved, both in the production and in the use of such a saw band.

This This object is achieved according to the invention by the features of a saw band of steel for a band-sawing machine having band back and a row of teeth with a number of teeth, wherein at least the row of teeth is provided with a hard material coating.

The coating according to the invention of at least the row of teeth of the saw band according to the invention makes a very much longer edge life possible, which apart from the longer time for which these saw bands can be used also allows greater intervals between changing used saw bands.

A further advantage of the saw band according to the invention is that of the consequently higher possible cutting speeds and perhaps higher possible feed rate. Furthermore, on account of the reduced friction, the coating can lead to very quiet and uniform running of the saw band, as a result of which considerably lower feeding forces are required.

A saw band according to the invention or a corresponding band saw consists of an HSS- (high-speed steel) based material, on which a hard layer is applied by means of PVD or paCVD methods. By virtue of their greater thermal stability, high-speed steels are ideal for coating by PVD or paCVD processes, since the annealing temperatures of these steels are usually significantly above 500° C., and consequently coating in the range of 500° C. is possible without any problem, which ensures significantly better layer/base material bonding in comparison with low-temperature processes.

In a preferred embodiment, the layer thickness on the tool flank is greater than the layer thickness on the side faces of a saw tooth of a band according to the invention.

Layers which are particularly well suited for saw coating are TiAlN and AlCrN layers, as can be produced for example on industrial coating systems of the type BAI1200 or RCS. Further layers that have also yielded a significant increase in cutting performance, at least in special combinations of layers and materials to be worked, are combinations of TiAlN, AlCrN, CrN and the carbonitrides and carbides of the corresponding layers, for example also as multilayer or gradient layers with increasing carbon content, combined with metallic or metal-free DLC (diamond like carbon) outer layers, as well as various Si-containing layers, for example TiAlSiN, AlCrSiN and the corresponding carbonitrides with an Si content of between 1 and 12 atomic % in relation to the total metal content.

Further particularly suited layer systems also comprise other hard materials, such as one or more metals of subgroups IV, V or VI of the periodic system (transition metals) or aluminum or silicon and their compounds. In particular, the nitrides, such as the known TiN, VN or TiSiN or SiN, carbides or carbonitrides, such as for example TiCN, VCN, borides, oxides such as for example Al₂O₃, (AlCr)₂O₃ and other mixtures of the corresponding non-metals, such as for example boronitrides, carbooxinitrides inter alia with the stated metals come into consideration for this. Multilayer systems as well as specially formed bonding and transitional layers may be of advantage for the working of specific materials.

A coating of a nitride-based material has proven to be particularly advantageous with respect to the edge life and the cutting speeds and the feed rates. In advantageous refinements of this, the coating may comprise TiN, TiCN, TiAlN and/or AlCrN. All of these materials may also be used here as alloys or mixtures.

A further coating that is very well suited for practical application may comprise WC/C as the outer layer, since this metal-containing DLC layer system has a particularly good run-in behavior, for example layer smoothing during the first cutting cycles. The systems as mentioned above come into consideration in particular as the supporting layer.

If, in an advantageous development of the invention, the coating has a thickness of 2-3 μm, this advantageously leads to very quiet, uniform running of the saw band and not to jamming or similar problems that could arise in the case of a coating with a greater thickness when sawing workpieces. However, the layer thickness also depends on the tooth division, the tooth geometry, the material to be worked and the material of the coating itself, as a result of which greater layer thicknesses may also be possible from case to case.

To optimize the cutting performance of a saw coated according to the invention, the correct layer thickness must therefore be set. In this respect, it has surprisingly been found in tests that thinner layers, for instance between 0.5 and 3 μm, in particular between 0.7 and 2 μm, produce much better cutting results than thick layers, from a layer thickness of about 4 μm and above.

The latter were only able to achieve a small improvement, or no improvement at all, in the cutting behavior in comparison with uncoated bands.

In a further refinement of the invention, it may be provided that the row of teeth consists of HSSE. Together with the coating according to the invention, this base material for the row of teeth leads to a particularly wear-resistant saw band.

In the prior art, uncoated saws are usually used with a rake angle geometry of a=α° for simple sawing tasks, such as the sawing of workpieces with a high carbon content (for example cast iron) or for workpieces with small cross sections or thin-walled profiles and pipes. Here, coated saws with a rake angle geometry of α=0° can be used particularly advantageously for the sawing of hard materials, such as tool steels, for example X38CrMoV5-1, material number 1.2343 with a hardness of up to HB₃₀=235. This is of particular advantage, since this saw band geometry can be produced more easily and at lower cost than geometries with a greater rake angle and possibly additionally curved tool face. Consequently, it is possible in spite of the additional coating to produce the bands for hard sawing operations or for the sawing of large solid geometries, in particular diameters, at low production costs. In addition, it has also been possible to test tooth geometries with a negative rake angle, so that a rake angle range between −5 and +5°, but with preference between −2 and 3°, comes into consideration for hard sawing with coated saw blades.

In the case of very effectively lubricating soft materials, on the other hand, such as VA stainless steels, for example X6Cr17, material number 1.4016 with a hardness of up to HB₃₀=185, it has been possible to achieve the best results with an aggressive tooth geometry at a rake angle of α=10°. Similar results can be achieved in a range of α=10±3°.

It has been possible to achieve a further improvement for various applications by beveling the tool flank at an angle between β=1 and 5°, with preference β=2 to 3°.

The object is achieved in terms of the method for the production of a saw band by the features of a hard material coating being applied by means of a vacuum coating process at least to the row of theeth of the saw band, and tips of the teeth being rounded in a defined manner before the coating process.

By rounding the tips of the teeth in a defined manner before the coating process, the best results regarding the durability of the saw band can be achieved, since in this manner it can be avoided that the coated regions of the saw band break away during the first use of the saw band. Furthermore, this rounding of the tips of the teeth makes the usual running-in of the saw band unnecessary.

A saw band coated according to the invention can be achieved with very good results in a method that can be easily implemented if, in an advantageous development, the material forming the coating is applied by means of PVD or paCVD methods at a temperature of 450-550° C., preferably about 500 to 550° C.

Furthermore, it may be provided that burr is removed at least from the row of teeth before the coating process. This removing of burr is a very simple and efficient way of rounding the tips of the teeth in a defined manner.

Still further, at least the row of teeth can be brushed to remove burr before the coating is applied. As an alternative to this, at least the row of teeth may also be shot-peened to remove burr before the coating is applied. Such removal of burr from the row of teeth prevents the burr from breaking off during the later use of the saw band, which would result in an uncoated surface of the saw band.

If, in an advantageous refinement of the method, only the row of teeth up to the transition to the band back is provided with the coating, this leads to a lowering of the costs for the production of the saw band according to the invention by saving coating material. This does not cause any reduction in the quality of the saw band according to the invention, since the non-coated band back has no cutting function. For this purpose it is possible, for example, to combine cut-to-length saw bands into stacks and coat them together, for example in known cartridge holders. In particular if the row of teeth consists of a different material than the band back, it may be advantageous if the row of teeth is welded to the band back.

Furthermore, it may be provided that the saw band is welded to a ring after the coating. In this way, immediate use of the saw band in a band-sawing machine is possible.

Very easy handling of the saw band during the coating is obtained if, in an advantageous development of the method according to the invention, the saw band is coated in the form of a coil, therefore wound into a spiral before the coating and secured in this form in the coating installation, the rows of teeth then all pointing in the same direction. This procedure also leads to a considerable cost reduction for the method, since a relatively great saw band length can be coated simultaneously.

According to the invention, a number of the spirally wound saw bands are mounted on holders and are coated together in one batch.

### BRIEF DESCRIPTION OF THE DRAWINGS

FIG. 1 shows a tooth;

FIG. 2 shows a detail of a saw band;

FIG. 3 shows an uncoated tooth and a coated tooth in cross section; and

FIG. 4 shows a coating installation;

FIG. 5 to FIG. 9 show diagrams of sawing tests with the saw band according to the invention.

### DETAILED DESCRIPTION

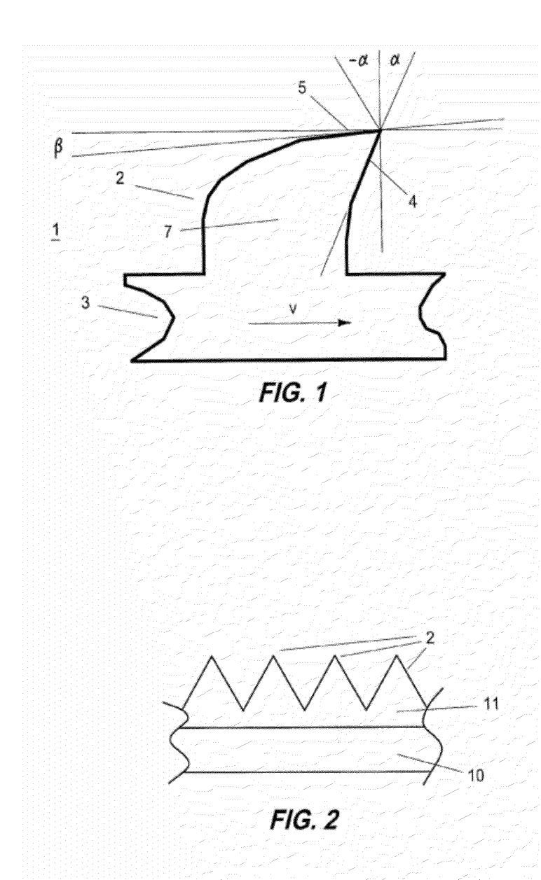

FIG. 1 shows in a schematic detail a tooth 2 of a saw band 1 with a saw back 3, the tooth having a tool face 4 with a rake angle α, a tool flank 5 with a clearance angle β and a side face 7.

The saw band may be formed as a closed ring and be fitted in a way known per se on a band-sawing machine. The direction of the cutting speed of the saw band 1 is indicated by the arrow designated by “v” in FIG. 1. Such saw bands are used in band-sawing machines in both horizontal and vertical orientation. Depending on the type of use, the workpiece is then moved toward the saw band 1, or vice versa.

In FIG. 2, a detail of the saw band 1 is represented. Here it can be seen that the saw band 1 has a band back 10, on which the saw band 1 is guided within the band-sawing machine in a way that is not represented but is known per se, and also a row of teeth 11 having a number of teeth 2. The band back 10 preferably consists of a relatively simple, “soft” steel, whereas the row of teeth 11 consists of a high-speed steel, preferably of HSSE. The use of a more simple steel for the band back 10 allows costs to be saved and the flexibility of the saw band 1 to be increased. A welding method is to be preferred for connecting the row of teeth 11 to the band back 10.

In order in particular to increase the edge life, but preferably also the cutting speed and perhaps the feed rate of the saw band 1, at least the row of teeth 11 is provided with a coating increasing the wear resistance. The coating, which cannot be seen in the drawings, may comprise, for example, a material as mentioned above or consist of such a material. The coating also contributes to a reduction in the cutting force of the saw band 1.

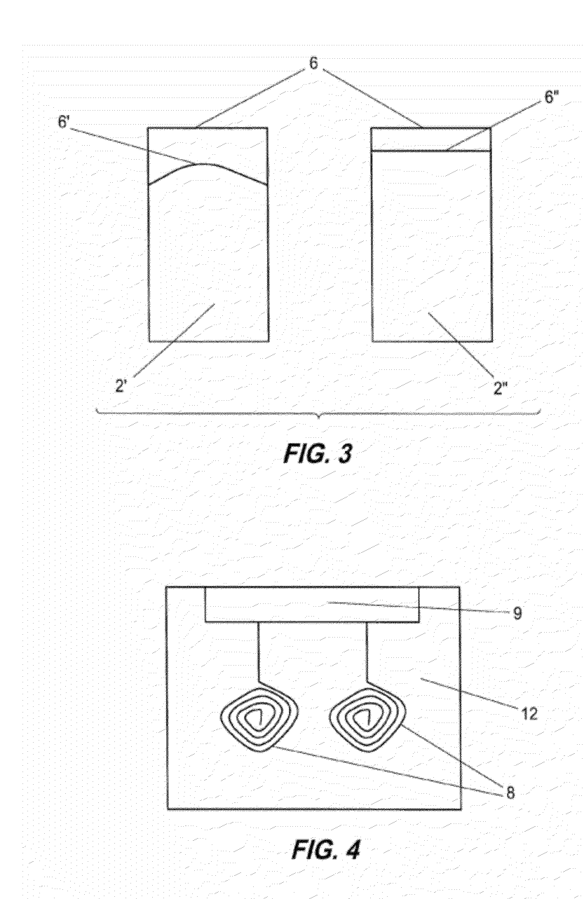

FIG. 3 schematically shows in cross section a tooth 2′ that is uncoated or coated with a conventional layer and also a tooth 2″ that is coated with a layer according to the invention after prolonged use. The tip or geometry of the unused tooth is respectively represented by a dashed line 6. The uncoated tooth shows greater wearing of the tip 6′ and rounding of the tip 6′ in cross section after the same number of cuts. The coated tooth 2″, on the other hand, shows less wearing of its tip 6″ and no or little rounding even after the layer has completely worn away. This has major advantages, since the guidance in the material that is ensured substantially by the edges of the tip 6 is consequently retained and a straight cut is possible even when the saw band is severely worn, whereas a band with greatly rounded teeth 2′ shows strong tendencies to run untrue, which increases the rate or rejection and/or the material consumption.

FIG. 4 shows in a very schematic representation a coating installation 12, with which a method for the production of the saw band 1 described above for the band-sawing machine can be carried out. Within this coating installation 12, the coating described above, which increases the wear resistance of the saw band 1, is applied at least to the row of teeth 11. The installation 12, preferably in the form of a vacuum coating installation, comprises, though not represented, the installations that are necessary for coating, such as sputter targets, evaporator crucibles or arc sources (also combined) along with their electrical operating devices; as well as gas feeding and regulating devices, in order for example to be able to separate oxidic or nitridic layers; vacuum pumps to create the pressure conditions necessary for operating a PVD or paCVD method, as well as heating devices, measuring instruments and further auxiliary drives. Installations of this type are state of the art as installations for coating tools and components.

In the present case, for coating the saw band 1, it is introduced into the coating installation 7 in a form wound up on a coil 8 and is suspended on a holder 9 provided there. In this case, the coil 8 may have a diameter of up to 50 cm, which leads to an overall length of the saw band 1 of 100 m. Preferably, only the row of teeth 6 up to the transition of the same to the band back 10, that is to say substantially up to the respective tooth gullet, is provided with the coating, in order to save coating material. After the coating, the saw band 1 is removed from the installation 12 and can be welded in a way not represented to such a ring as that represented in FIG. 1.

In order to avoid burr that is possibly located on the teeth 2 breaking off during the later use of the saw band 1, which would bring an uncoated region of the saw band 1 to its surface and consequently reduce its wear resistance considerably, in the present case at least the row of teeth 11 is brushed or shot-peened with relatively low pressure to remove burr before the coating is applied. After working, the respective tooth 5 has a small radius instead of the burr. In the case of brushing, a circulating brush may be used, brushing the saw band 1 wound up on the coil 8.

Generally, the tips or edges of the teeth are rounded in a defined manner before the coating process. With this rounding, the radius of the tip of the tooth is enlarged. For example, if the radius of the tooth is 0.01 mm after the mechanical processing, it can be 0.05 mm after the rounding of the tip. As a rule, a radius of 0.08 mm with a tolerance zone of +/−0.05 mm, particularly 0.05 mm with a tolerance zone of +/−0.01 mm, for the tip of the tooth leads to the best results in cutting. In this respect, the radius of the tip of the tooth shown in FIG. 1 is very small.

### EXAMPLES

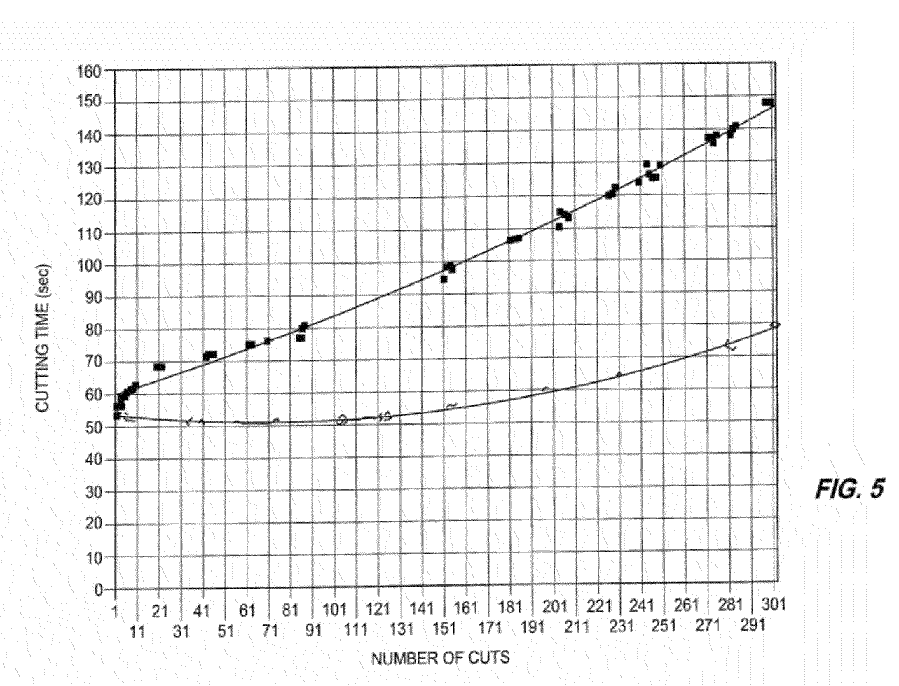

FIG. 5 shows very clearly the advantages of a saw band according to the invention. A pipe 91.45×14.3 mm of 100Cr6, material No. 1.3505, was worked with a saw band with a TiAlN coating of about 1 to 2 μm (Balinit FuturaNano, process FN1) and a rake angle of 0° at a cutting speed of 120 m/min. For an uncoated band, the cutting speed recommended by the manufacturer, namely 60 m/min, was used. The curves show the cutting time in dependence on the number of cuts. The upper curve shows the values for the uncoated band, the lower curve the values for the coated band. The overall cutting time for 300 parts with the coated saw band was 5 hours. The overall cutting time for 300 parts with the uncoated saw band was 8 hours and 24 minutes. After 300 cuts, the cutting time per cut of the coated band was already below half the cutting time of the uncoated band.

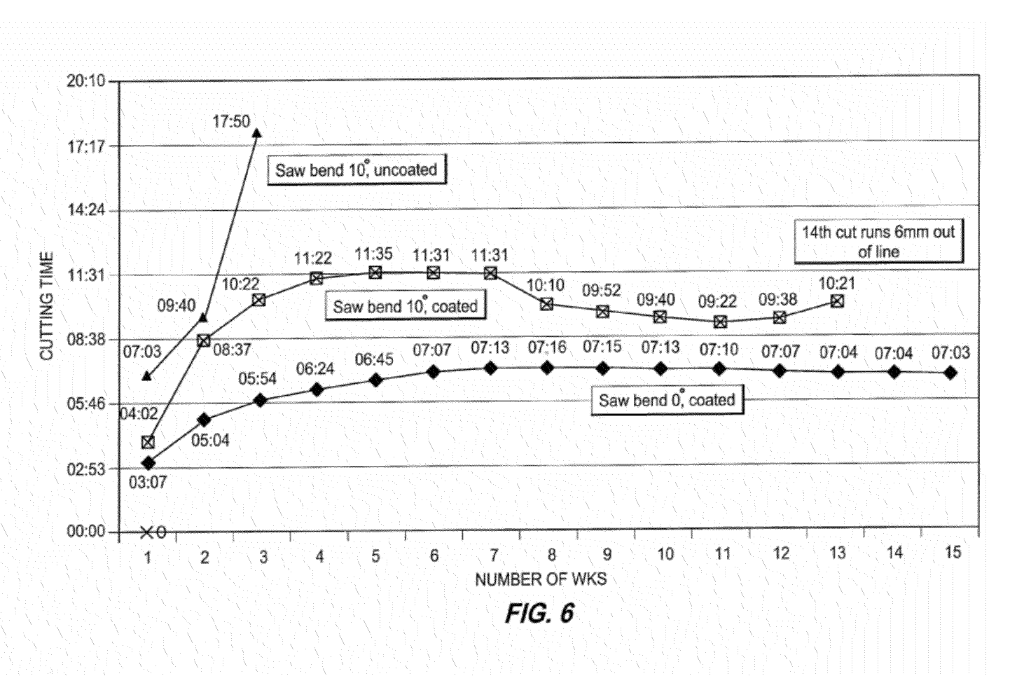

FIG. 6 shows two sawing tests on saw bands coated with about 1 to 2 □m of TiAlN (Balinit FuturaNano, as above) of different geometries on tool steel 80×80 mm, X38CrMoV5-1, material No. 1.2343. The cutting speed was 90 m/min, the cutting pressure 16 bar and the feed rate 4. The differences between the two bands lay exclusively in the tooth geometry, to be more precise the rake angle. It was found here, completely surprisingly, that the saw band with the smaller rake angle of 0° (curve with lozenge marking, at the bottom) was clearly superior to the saw band with the sharper rake angle of 10° (curve with square marking, in the middle), which is contrary to the experience with coated saw blades.

In a comparative test shown here only for “10° bands” with uncoated bands at half the cutting speed, that is to say 45 m/min (according to the manufacturer's recommendation), and otherwise the same conditions as specified above, the saw band with a rake angle of 0° was already blunt after one third of the first cut, the saw band with a rake angle of 10° was already blunt after half the first cut. The test was therefore only continued with the “10° band” (curve with triangle marking, at the top). However, already with the third cut, the cutting time was around 18 minutes, while the geometrically identical coated band required a cutting time of about 10 minutes, but the coated “0° band” only required a cutting time of about 6 minutes.

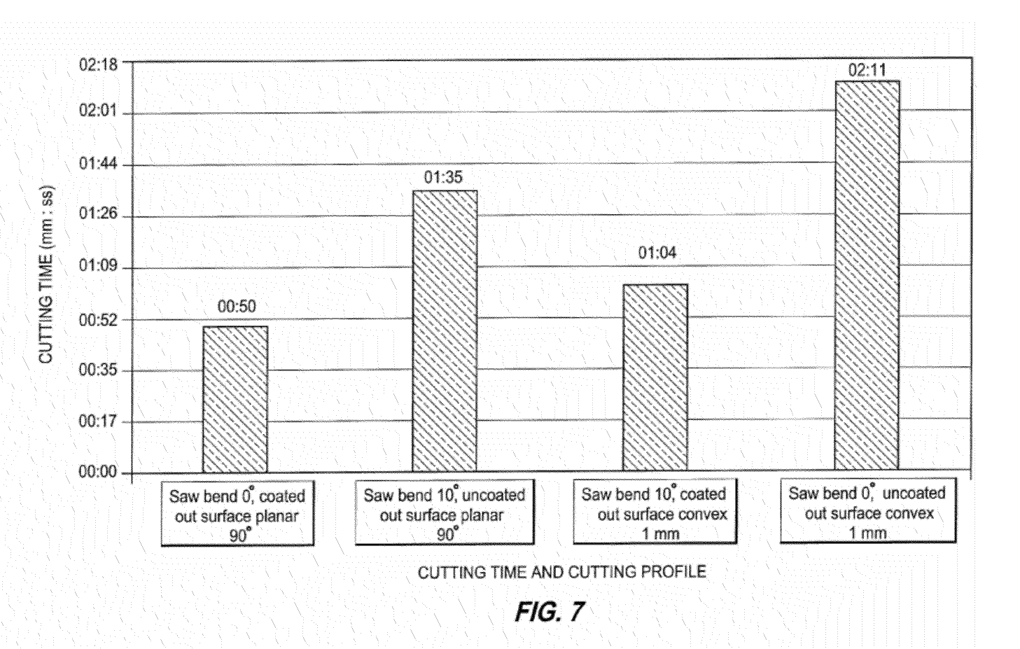

FIG. 7 shows a comparison of the cutting times of coated and uncoated saw bands of different tooth geometries. In this case, a solid heat-treatable steel C 45, material No. 1.0503, d=100 mm was sawn. The sawing parameters for the coated bands were respectively set as follows. The first result is shown by column 1 of FIG. 7:

Cutting speed 120 m/min;
Cutting pressure 18 bar; and
Feed rate 4.

If uncoated bands are operated with the same parameters, the cut becomes what is known as untrue, i.e. the cut runs out of line, which leads to rejection. Therefore, uncoated bands had to be operated at correspondingly lower cutting speed and pressure; the result is column 4 of FIG. 7:

Cutting speed 75 m/min;
Cutting pressure 12 bar; and
Feed rate 3.

This consequently allowed both for bands with a rake angle of 0° and bands with a rake angle of 10° to reduce the cutting time by about 50% as a result of the coating and it thereby being possible for the first time to operate at higher cutting speed and pressure. However, with the chosen cutting parameters, it was only possible to achieve a planar cut for “0° saw bands”. In the case of coated and uncoated “10° bands”, on the other hand, a convexity of the cut surface with a maximum deviation of 1 mm from the cut plane was established, which would lead to either rejection or reworking of the workpieces.

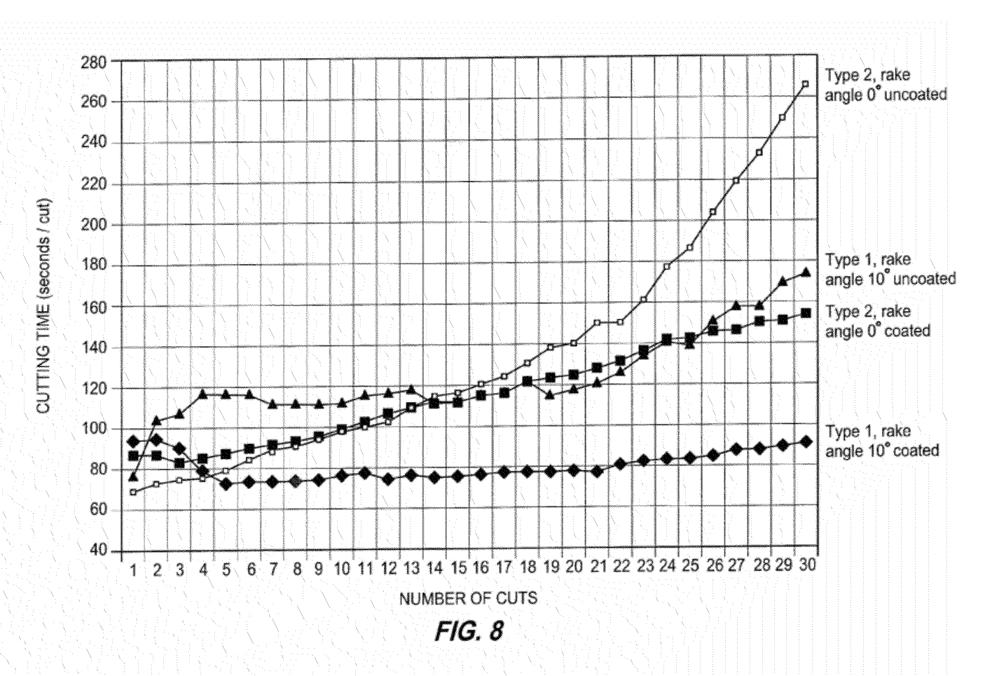

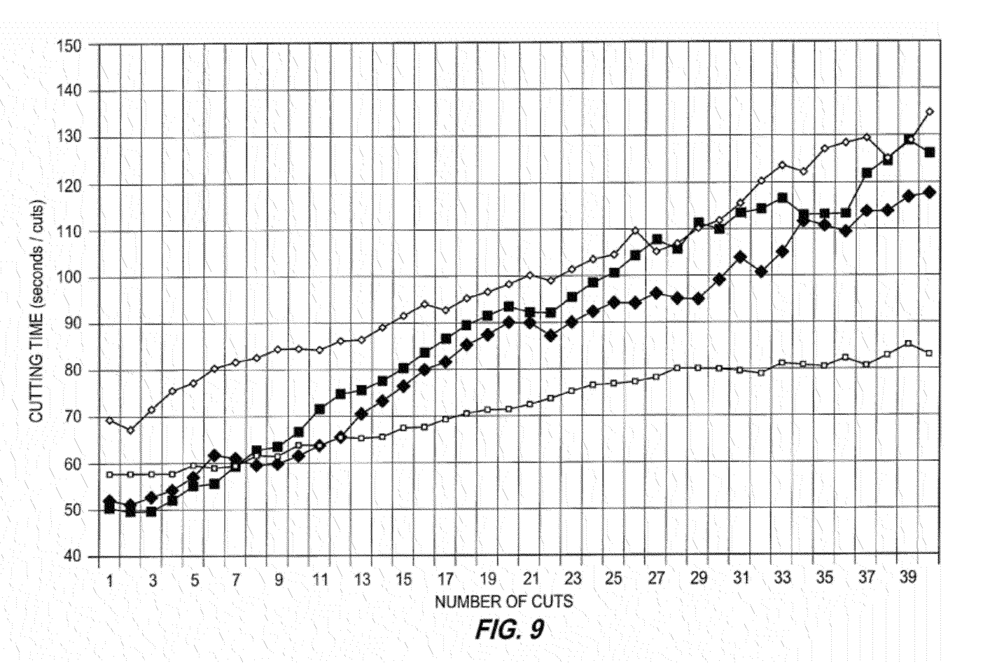

FIGS. 8 and 9 show the results of sawing tests with saw blades of different geometries (types 1-3) with rake angles of 0°/10° in coated and uncoated versions. The workpiece in FIG. 8 was ferritic stainless steel, X6Cr17, material 1.4016. The width of cut was d=102 mm, the cutting speed 120 m/min and the feeding pressure 6.0. In FIG. 9, heat-treatable steel, 42CrMo4, material No. 1.7225 was worked with a depth of cut of d=90 mm, a cutting speed of 90 m/min and a feeding pressure of 4.4. In all cases, the superiority of coated saw bands over uncoated saw bands was evident.

In the relatively soft ferritic stainless steel, the best cutting result was achieved with a coated saw blade with a rake angle of 10°. In the relatively hard heat-treatable steel, however, the best result was achieved with a coated band with a rake angle of 0°, which is all the more astounding since an uncoated band with this rake angle yielded the poorest results.

A further sawing test was carried out on solid heat-treatable steel/cold extruding steel 42CrMo4V, material No. 1.7225, d=300 mm at a cutting speed of 50 m/min, a cutting pressure of 16 bar and a feed rate of 3, determining the edge life and total cut area of an uncoated saw band with a rake angle of 16° and a coated saw band with a rake angle of 0°. In this case, the uncoated band was worn after 6 hours, a total quantity of 21 cuts and a total cut area of 1.48 m². With the coated band, it was possible within its useful life of 8 hours and 53 minutes to achieve 31 cuts and a total cut area of 2.19 m², which corresponds to an increase in the quantity of cuts and total cut area of just under 50%.

In addition, it was found in long-time sawing tests, in which pipe material with a diameter of 91 mm, a wall thickness of 16 mm of 16MnCr5, material No. 1.7131 (HB 140 to 207) was sawn, that in the case of an uncoated saw band with a rake angle of 10° the cut ran out of the angle by 1 mm over the diameter after 500 to 600 cuts. On the other hand, with an identical, but coated, saw band, 900 to 1200 cuts could be achieved without observing that the band ran out of the angle. This is all the more surprising since coated saw bands still maintain the angle even when they are blunt at the end of their service life. Consequently, an automated overnight sawing operation is quite possible for example.

1. A saw band of steel for a band-sawing machine, the saw band comprising a band back and a row of teeth having a number of teeth, at least the row of teeth is provided with a hard material coating.

2. The saw band as claimed in claim 1, wherein the thickness of the hard material coating on the tool flanks of the row of teeth is greater than on the side faces.

3. The saw band as claimed in claim 1, wherein the hard material coating substantially covers only tool flanks and tool faces.

4. The saw band as claimed in claim 1, wherein the coating contains one or more metals of subgroups IV, V or VI of the periodic system or aluminum or silicon.

5. The saw band as claimed in claim 4, wherein the coating contains the nitrides, oxides, carbides, carbonitrides or borides of the aforementioned metals or mixtures thereof.

6. The saw band as claimed in claim 5, wherein the coating contains TiAlN, AlCrN, metallic or metal-free DLC, TiAlSiN, TiAlCN or WC/C.

7. The saw band as claimed in claim 4, wherein the coating takes the form of a multilayer system.

8. The saw band as claimed in claim 7, wherein the multilayer system has bonding and transitional layers.

9. The saw band as claimed in claim 1, wherein the coating has a thickness of less than 4 μm, with preference of 0.5 to 3 μm, with particular preference of 0.7 to 2 μm.

10. The saw band as claimed in claim 1, wherein the band back and the row of teeth consist of different types of steel and the row of teeth consists of a high-speed steel, preferably of HSSE.

11. A saw band for hard sawing as claimed in claim 1, wherein the rake angle α is equal to −5 to 5°, but with preference −3 to 3°.

12. The saw band as claimed in claim 10, wherein the rake angle α is equal to 0°.

13. A saw band for sawing soft metallic materials as claimed in claim 1, wherein the rake angle α is equal to 10±3°.

14. The saw band as claimed in claim 1, wherein the clearance angle β is equal to 0 to 5°, but with preference 1 to 3°.

15. (canceled)

16. A method for the production of a saw band, the method comprising a hard material coating being applied by means of a vacuum coating process at least to the row of teeth of the saw band, and tips of the teeth being rounded in a defined manner before the coating process; and
wherein the vacuum coating process is a PVD or paCVD method or a combination thereof.

17. The method as claimed in claim 16, wherein the hard material coating is applied at temperatures of up to 550° C.

18. The method as claimed in claim 16, wherein the saw band is welded to a ring after the coating.

19. The method as claimed in claim 16, wherein the saw band being wound up spirally to form a coil and coated in this form.

20-21. (canceled)
